(19) United States
(12) Patent Application Publication
(10) Pub. No.: US 2026/0372003 A1
(43) Pub. Date: Nov. 19, 2026

(54) METHOD OF MANUFACTURING SEMICONDUCTOR AND SEMICONDUCTOR MANUFACTURING DEVICE

(71) Applicant: Mitsubishi Electric Corporation, Tokyo (JP)

(72) Inventors: Yusuke UCHIDA, Tokyo (JP); Harutaka SASAKI, Tokyo (JP)

(73) Assignee: Mitsubishi Electric Corporation, Tokyo (JP)

(21) Appl. No.: 19/547,770

(22) Filed: Feb. 24, 2026

(30) Foreign Application Priority Data
May 16, 2025 (JP) 2025-082507

(51) Int. Cl. H10P 72/30

(52) U.S. Cl. CPC H10P 72/3306; H10P 72/3302; H10P 72/3411

(57) ABSTRACT

An object of the present disclosure is to provide a semiconductor manufacturing method and a semiconductor manufacturing device capable of preventing a robot hand from having contact with a wafer when the robot hand takes out the wafer. A semiconductor manufacturing method according to the present disclosure is a semiconductor manufacturing method of manufacturing a semiconductor device including steps of: (a) blowing air to at least one wafer disposed on a support portion in a cassette from below using an air generator disposed on an outer portion of the cassette; and (b) raising the wafer from the support portion to take out the wafer from the cassette using a robot hand while blowing the air to the wafer, wherein in the step (a), the air generator blows the air toward half of a range of a side of taking out the wafer from the cassette in the wafer.

### BACKGROUND

### Technical Field

The present disclosure relates to a semiconductor manufacturing method of manufacturing a semiconductor device and a semiconductor manufacturing device manufacturing a semiconductor device.

### Description of the Background Art

Disclosed conventionally is a technique of pushing up a center portion of a wafer from a lower side of a cassette by a support rod or air, thereby correcting a warpage of the wafer for a problem that transfer of the wafer is blocked by a warpage of the wafer housed in the cassette by self-weight (for example, refer to Japanese Patent Application Laid-Open No. 2012-84715).

### SUMMARY

In Japanese Patent Application Laid-Open No. 2012-84715, the warpage of only the wafer housed in a bottom of the cassette is corrected. Thus, when the other wafer is housed below the wafer to be corrected, the warpage of the wafer to be corrected cannot be corrected. In Japanese Patent Application Laid-Open No. 2012-84715, the center portion of the wafer is pushed up; however, a sag of the wafer on a side of an opening portion of the cassette by self-weight cannot be corrected. Accordingly, there is a possibility that when a robot hand is inserted into the cassette to take out the wafer, the robot hand has contact with a sag portion of the wafer.

An object of the present disclosure is to provide a semiconductor manufacturing method and a semiconductor manufacturing device capable of preventing a robot hand from having contact with a wafer when the robot hand takes out the wafer.

A semiconductor manufacturing method according to the present disclosure is a semiconductor manufacturing method of manufacturing a semiconductor device including steps of: (a) blowing air to at least one wafer disposed on a support portion in a cassette from below using at least one air generator disposed on an outer portion of the cassette; and (b) raising the wafer from the support portion to take out the wafer from the cassette using a robot hand while blowing the air to the wafer, wherein in the step (a), the air generator blows the air toward half of a range of a side of taking out the wafer from the cassette in the wafer.

According to the present disclosure, it is possible to prevent the robot hand from contact with the wafer when the robot hand takes out the wafer.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a diagram illustrating an example of a configuration of a semiconductor manufacturing device according to an embodiment 1.

FIG. 2 is a diagram illustrating an example of blowing air to a wafer according to the embodiment 1.

FIG. 3 is a diagram illustrating an example of blowing air to the wafer according to the embodiment 1.

FIG. 4 is a diagram illustrating an example of blowing air to the wafer according to the embodiment 1.

FIG. 5 is a diagram illustrating an example of blowing air to the wafer according to the embodiment 1.

FIG. 6 is a diagram for explaining a semiconductor manufacturing method according to the embodiment 1.

FIG. 7 is a diagram for explaining the semiconductor manufacturing method according to the embodiment 1.

FIG. 8 is a diagram for explaining the semiconductor manufacturing method according to the embodiment 1.

FIG. 9 is a diagram for explaining the semiconductor manufacturing method according to the embodiment 1.

FIG. 10 is a diagram for explaining the semiconductor manufacturing method according to the embodiment 1.

FIG. 11 is a diagram for explaining the semiconductor manufacturing method according to the embodiment 1.

FIG. 12 is a diagram illustrating an example of a configuration of a semiconductor manufacturing device according to an embodiment 2.

FIG. 13 is a diagram illustrating an example of blowing air to a wafer according to the embodiment 2.

FIG. 14 is a diagram illustrating an example of blowing air to the wafer according to the embodiment 2.

FIG. 15 is a diagram illustrating an example of blowing air to the wafer according to the embodiment 2.

FIG. 16 is a diagram for explaining a semiconductor manufacturing method according to the embodiment 2.

FIG. 17 is a diagram for explaining the semiconductor manufacturing method according to the embodiment 2.

FIG. 18 is a diagram for explaining the semiconductor manufacturing method according to the embodiment 2.

FIG. 19 is a diagram for explaining the semiconductor manufacturing method according to the embodiment 2.

FIG. 20 is a diagram illustrating an example of a semiconductor manufacturing device according to an embodiment 3.

FIG. 21 is a diagram for explaining a semiconductor manufacturing method according to the embodiment 3.

FIG. 22 is a diagram for explaining the semiconductor manufacturing method according to the embodiment 3.

FIG. 23 is a diagram for explaining the semiconductor manufacturing method according to the embodiment 3.

FIG. 24 is a diagram for explaining the semiconductor manufacturing method according to the embodiment 3.

FIG. 25 is a diagram for explaining the semiconductor manufacturing method according to the embodiment 3.

FIG. 26 is a diagram for explaining the semiconductor manufacturing method according to the embodiment 3.

FIG. 27 is a diagram for explaining the semiconductor manufacturing method according to the embodiment 3.

FIG. 28 is a diagram for explaining the semiconductor manufacturing method according to the embodiment 3.

FIG. 29 is a diagram for explaining the semiconductor manufacturing method according to the embodiment 3.

FIG. 30 is a diagram for explaining the semiconductor manufacturing method according to the embodiment 3.

### DESCRIPTION OF THE PREFERRED EMBODIMENTS

### Embodiment 1

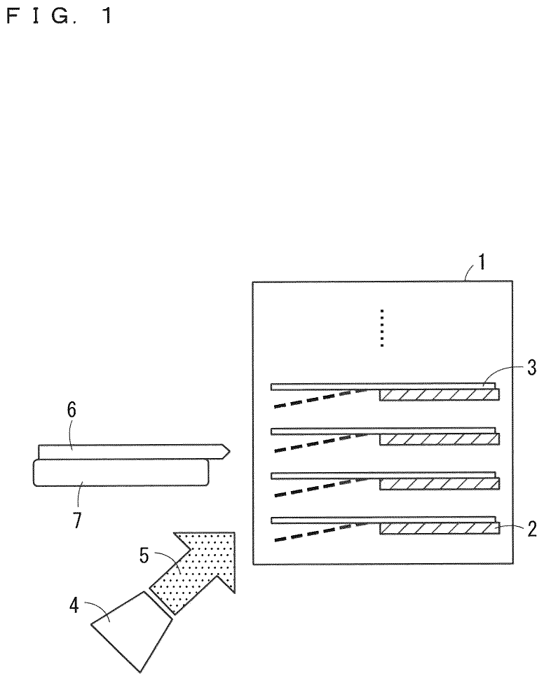

FIG. 1 is a diagram of an example of a configuration of a semiconductor manufacturing device according to the embodiment 1 seen from a lateral side. A semiconductor device includes a cassette 1 including an opening portion in at least a part of a region housing a wafer, an air generator 4, and a robot hand 6. The robot hand 6 is disposed in a transfer robot 7 described hereinafter.

The cassette 1 includes a support portion 2 on which a wafer 3 is disposed. Although four wafers 3 are disposed on four support portions 2, respectively, in the example in FIG. 1, the number of wafers 3 and the support portions 2 may be one, or may also be five or more. The wafer 3 is an SiC wafer (semiconductor device), for example.

The air generator 4 is disposed on an outer portion of the cassette 1, and blows air 5 to all of the wafers 3 from below.

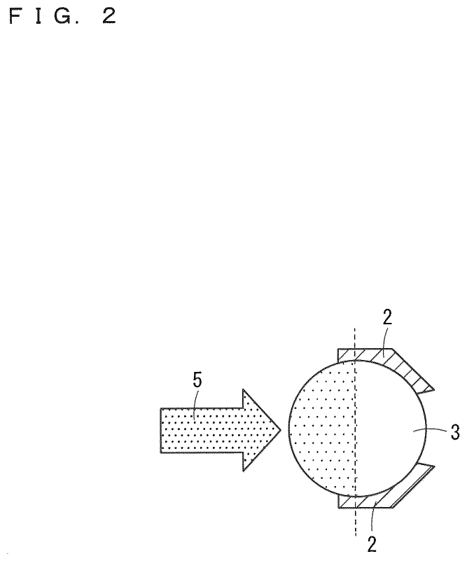

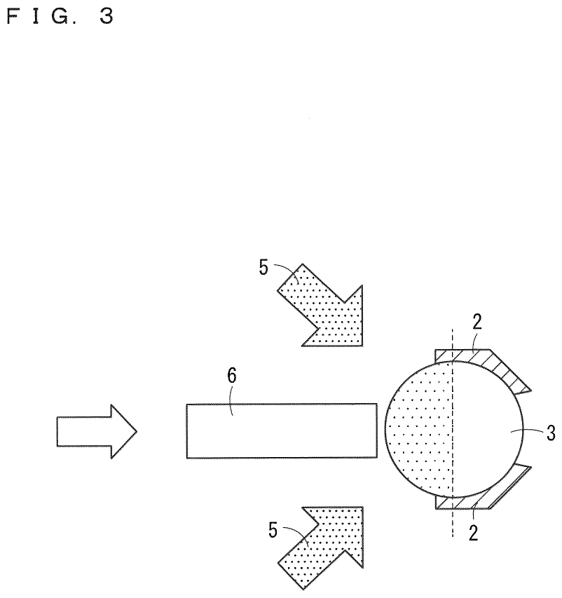

FIGS. 2 and 3 are diagrams illustrating an example of blowing the air 5 to the wafer 3. FIG. 2 illustrates that the air 5 is blown to all of the wafers 3 from a front surface of the cassette 1, and FIG. 3 illustrates that the air 5 is blown thereto from right and left sides (sides of an opening portion from which the wafer 3 is taken out) of the cassette 1. FIGS. 2 and 3 are diagrams illustrating the air 5 blown to the wafer 3 seen from an upper side.

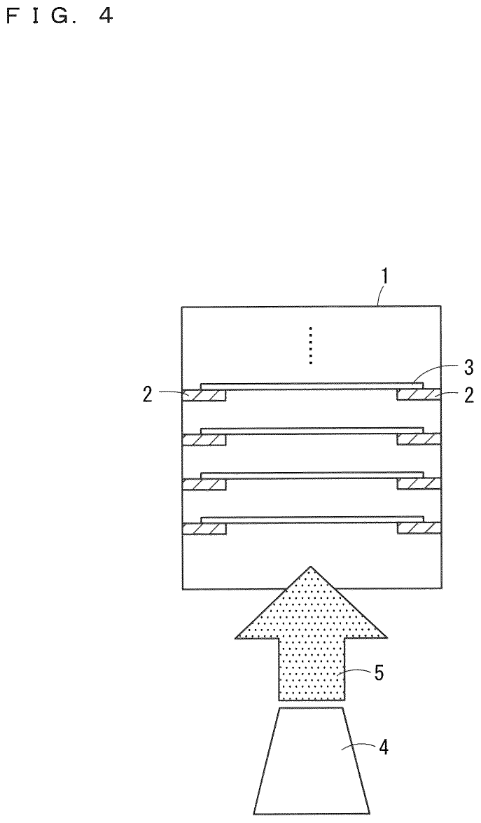

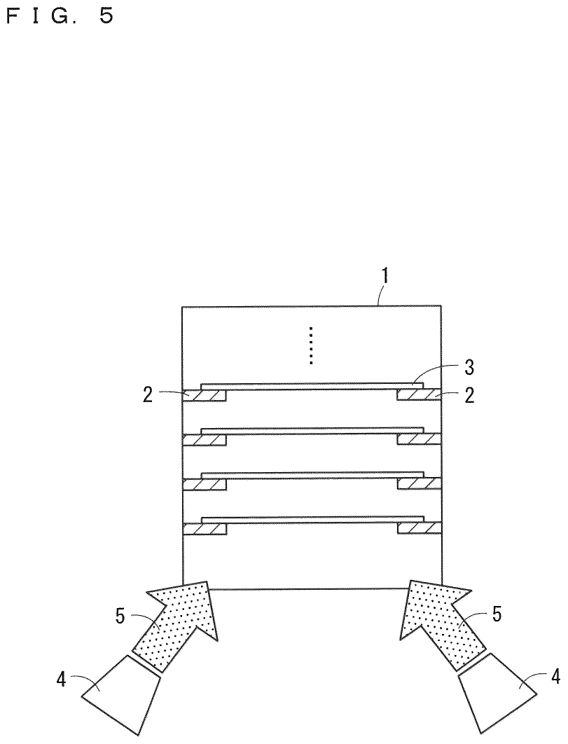

FIGS. 4 and 5 are diagrams illustrating an example of blowing the air 5 to the wafer 3 in FIGS. 2 and 3 described above and an arrangement position of the air generator 4. FIG. 4 illustrates that the air 5 is blown to all of the wafers 3 from the front surface of the cassette 1, and FIG. 5 illustrates that the air 5 is blown thereto from right and left sides of the cassette 1. FIGS. 4 and 5 are diagrams illustrating the air 5 blown to the wafer 3 seen from a side of the front surface.

In the case of the example of blowing the air 5 illustrated in FIGS. 2 and 4, the air generator 4 may be disposed on an outer portion and below the wafer 3 along a center portion of the wafer 3. In the case of blowing the air 5 illustrated in FIGS. 3 and 5, the air generator 4 may be disposed in a plurality of positions away from a movement route (an arrow direction illustrated in FIG. 3) of the robot hand 6. FIG. 4 illustrates that one air generator 4 is disposed, and FIG. 5 illustrates that two air generators 4 are disposed. However, the number of air generators 4 is not limited thereto. The air generator 4 having a larger area of an air generation portion than the robot hand in a width direction (up-down direction in a paper sheet is illustrated in FIGS. 2 and 3) of the cassette 1 may be disposed.

As illustrated in FIGS. 2 and 3, the air generator 4 may eject the air 5 to the whole width direction of the cassette 1. The air generator 4 blows the air 5 to half of a near side of the wafer 3 (a hatched portion in the wafer 3). Herein, the half of the near side of the wafer 3 indicates half of a range of the side of the front surface (the side on which the wafer 3 is taken out from the cassette 1) of the cassette 1 in the wafer 3.

Since the air 5 is blown to the half of the near side of the wafer 3, a sag and a warpage of the wafer 3 can be reduced. Herein, the sag of the wafer 3 indicates that a part of the wafer 3 protruding to the side of the front surface of the cassette 1 from the support portion 2 is bent downward by self-weight while the wafer 3 is disposed on the support portion 2 (a portion of the wafer 3 shown by a broken line in FIG. 1). The warpage of the wafer 3 indicates that a center portion of the wafer 3 is bent downward by self-weight while the wafer 3 is disposed on the support portion 2. In the example in FIGS. 2 and 4, the air 5 is supplied to the whole width direction of the cassette 1 and the half of the near side of the wafer 3, the sag and the warpage of the wafer 3 are easily suppressed even when the robot hand (refer to FIGS. 1 and 3) blocks the air 5 in movement.

As illustrated in FIGS. 3 and 5, each air generator 4 blows the air 5 to the whole width direction of the cassette 1 and the half of the near side of the wafer 3 (the hatched portion in the wafer 3). Since each air generator 4 is disposed in the position away from the movement route of the robot hand 6, efficiency of blowing the air 5 to the wafer 3 is improved. Since the air 5 is not blocked by the robot hand 6, the sag and the warpage of the wafer 3 can be accurately and efficiently suppressed.

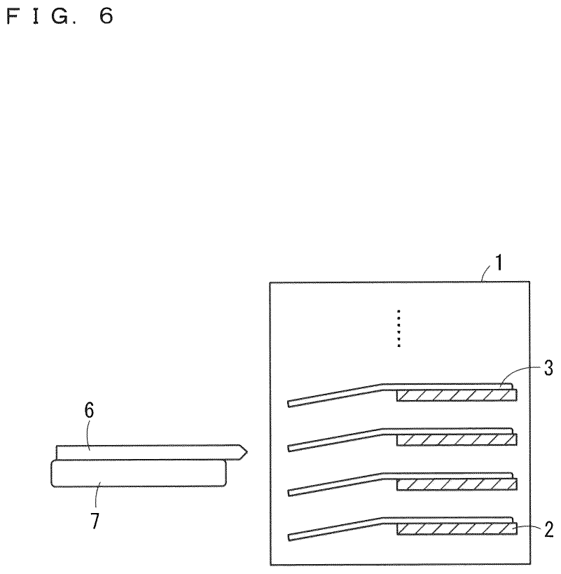

FIGS. 6 to 11 are diagrams for explaining the semiconductor manufacturing method according to the embodiment 1. As illustrated in FIGS. 6 to 11, the transfer robot 7 includes the robot hand 6. Described hereinafter is a method of taking out the third wafer 3 from the bottom (also referred to as “the target wafer 3” hereinafter) from the cassette 1.

As illustrated in FIG. 6, the front side of each wafer 3 disposed on the support portion 2 in the cassette 1 sags, and the center portion thereof is warped. When the robot hand 6 is inserted below the target wafer 3 in such a state, the robot hand 6 has contact with the target wafer 3.

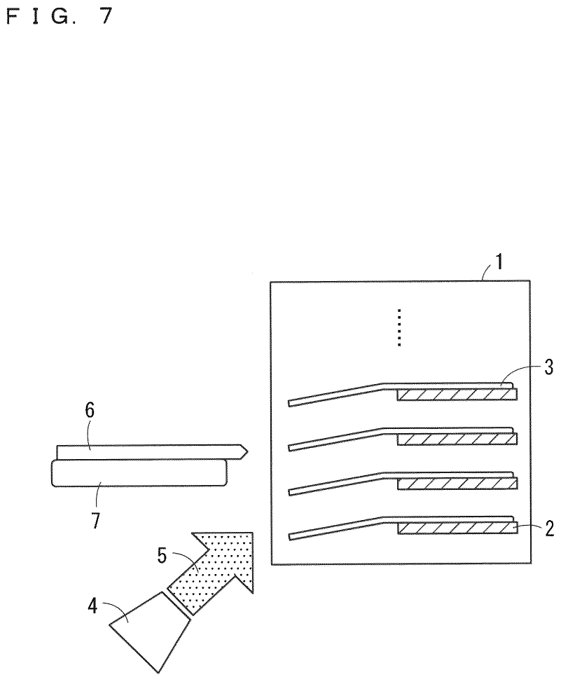

As illustrated in FIG. 7, the air generator 4 blows the air 5 to each wafer 3. The method of blowing the air 5 to each wafer 3 may be any of the method illustrated in FIGS. 2 and 3 or FIGS. 4 and 5.

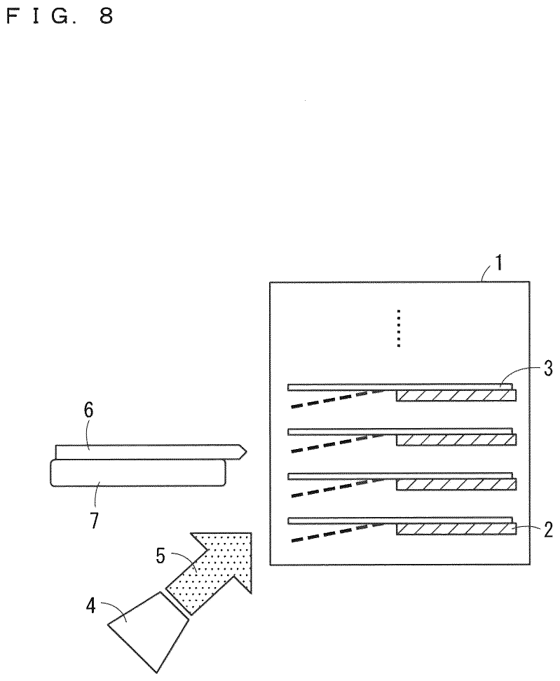

As illustrated in FIG. 8, when the air generator 4 blows the air 5 to each wafer 3, the sag of each wafer 3 (a broken line in FIG. 8) is reduced. Although not shown in FIG. 8, the warpage of each wafer 3 is also reduced.

The air generator 4 may adjust a flow rate and pressure of the air 5 in accordance with at least one of the sag and the warpage of each wafer 3. A degree of the sag and the warpage of each wafer 3 may be measured using a measuring instrument or by eye. When the flow rate and the pressure of the air 5 are adjusted in accordance with at least one of the sag and the warpage of each wafer 3, the sag and the warpage of the wafer 3 can be accurately corrected.

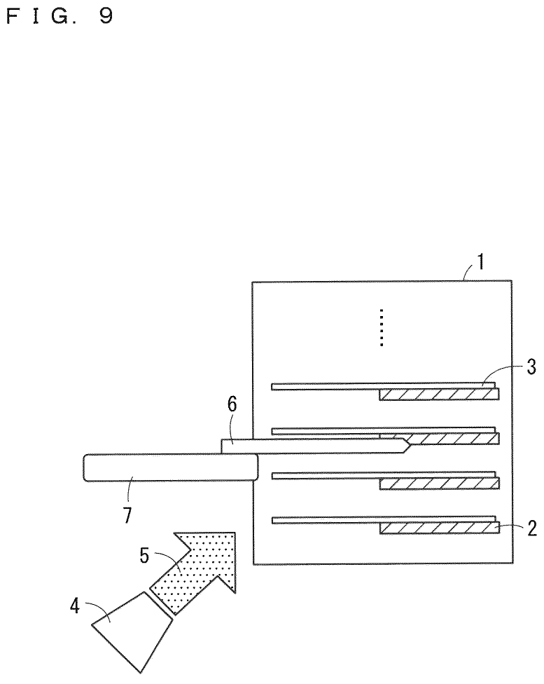

As illustrated in FIG. 9, the transfer robot 7 gets close to the cassette 1, and the robot hand 6 is inserted below the target wafer 3. At this time, the air 5 is being ejected from the air generator 4.

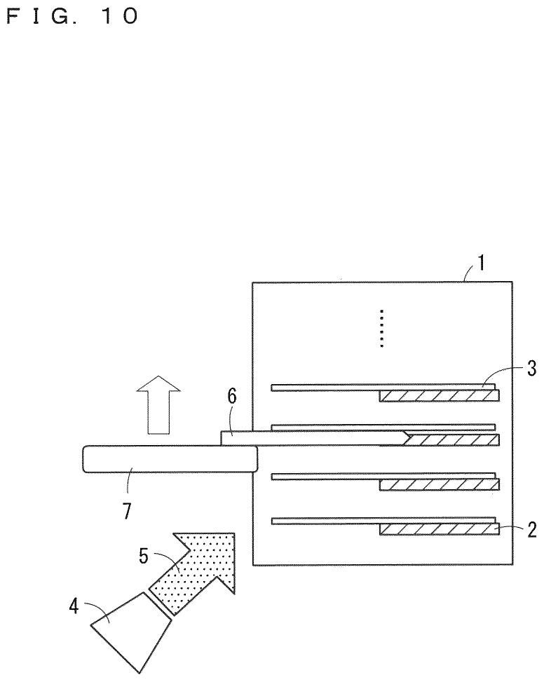

As illustrated in FIG. 10, the target wafer 3 is raised from the support portion 2 using the robot hand 6. Accordingly, the target wafer 3 is disposed on the robot hand 6.

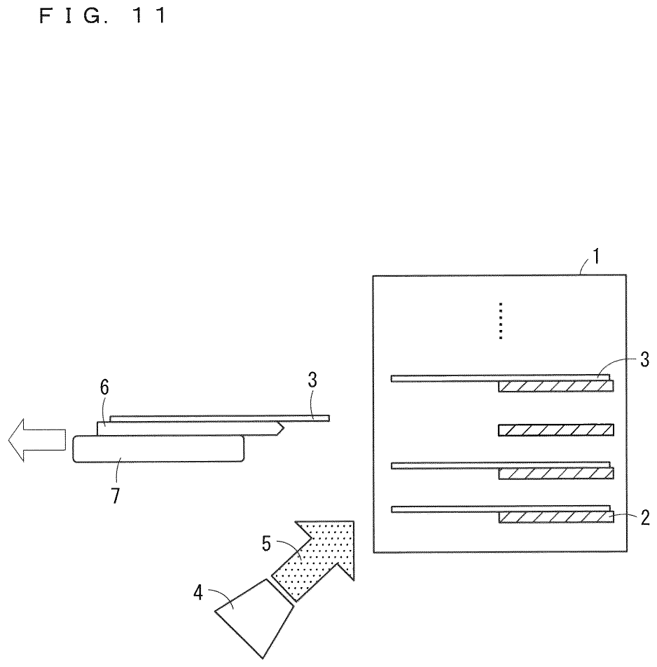

As illustrated in FIG. 11, the robot hand 6 is pulled out from the cassette 1. Accordingly, the target wafer 3 is taken out from the cassette 1. Subsequently, the transfer robot 7 transfers the target wafer 3 to various processing rooms.

According to the embodiment 1, the air 5 is blown to all of the wafers 3 housed in the cassette 1 from below using the air generator 4 disposed on the outer portion of the cassette 1. Thus, the sag and the warpage of all of the wafers 3 can be reduced. Accordingly, a clearance between the robot hand 6 and the wafer 3 can be ensured, and contact of the robot hand 6 with the wafer 3 can be prevented when the wafer 3 is taken out. Thus, the wafers 3 can be housed in the cassette 1 without reducing the number of wafers 3 which can be stored in the cassette 1. Particularly, the sag and the warpage of all of the wafers 3 can be reduced at the same time even not only in a case where only one wafer 3 is housed in the cassette 1 but also in a case where the plurality of wafers 3 are housed in the cassette 1. Thus, there is hardly influence of blocking of the air 5 caused by a shape of a bottom portion of the cassette 1 or a shape of the robot hand 6.

### Embodiment 2

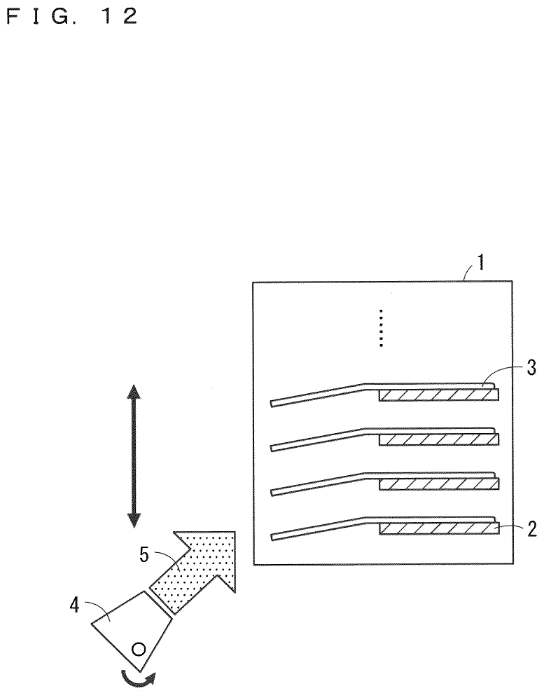

FIG. 12 is a diagram illustrating an example of a configuration of a semiconductor manufacturing device according to an embodiment 2. As illustrated in FIG. 12, the air generator 4 according to the embodiment 2 includes a movement mechanism which can move in a direction in which the plurality of wafers 3 are disposed (the up-down direction in FIG. 12) and an angle changing mechanism which can change an angle to the direction in which the plurality of wafers 3 are disposed. The other configuration is similar to that of the semiconductor manufacturing device according to the embodiment 1.

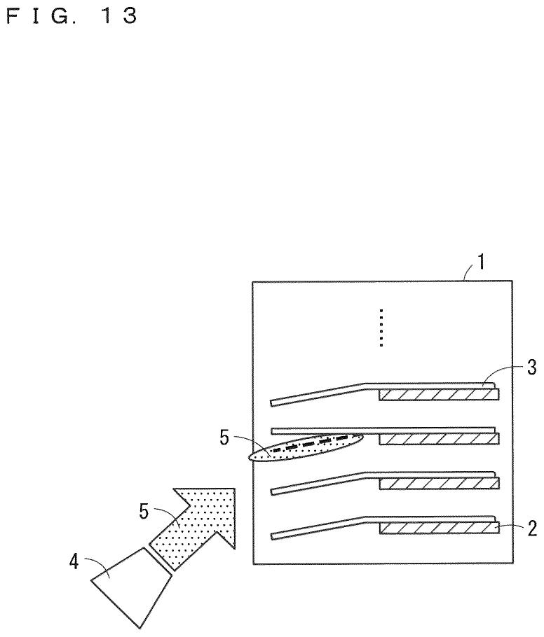

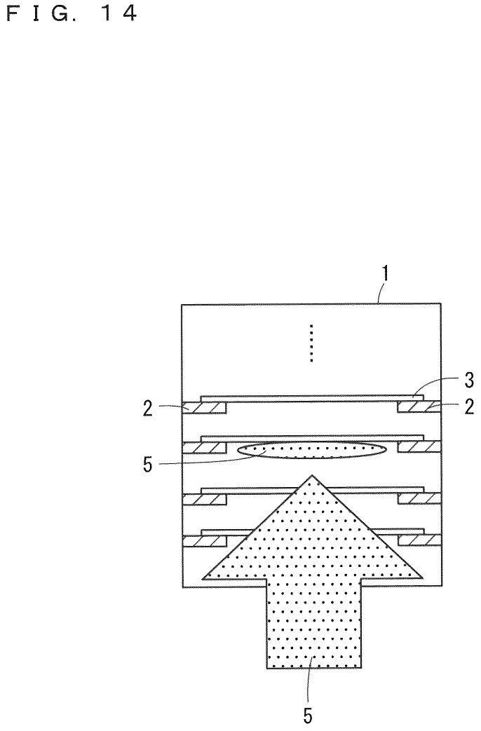

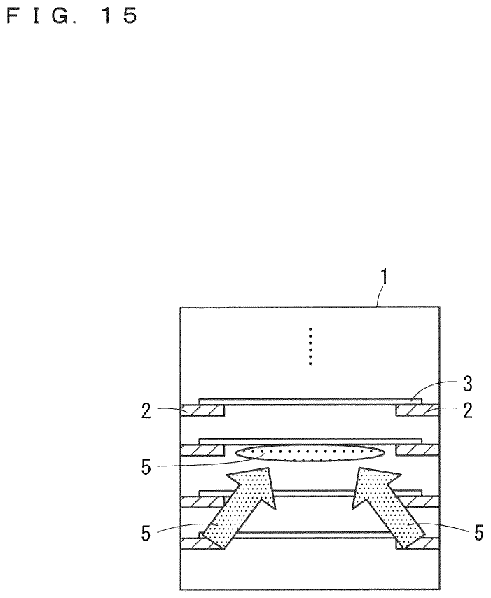

FIG. 13 is a diagram illustrating an example of blowing air 5 to the wafer 3 according to the embodiment 2. As illustrated in FIG. 13, when the position and the angle of the air generator 4 are adjusted, the air 5 can be blown to the specific wafer 3. The method of blowing the air 5 to the wafer 3 may be a method of blowing the air 5 to the whole width direction of the cassette 1 as illustrated in FIG. 14 or a method of blowing the air 5 from a plurality of positions away from the movement route of the robot hand 6 as illustrated in FIG. 15.

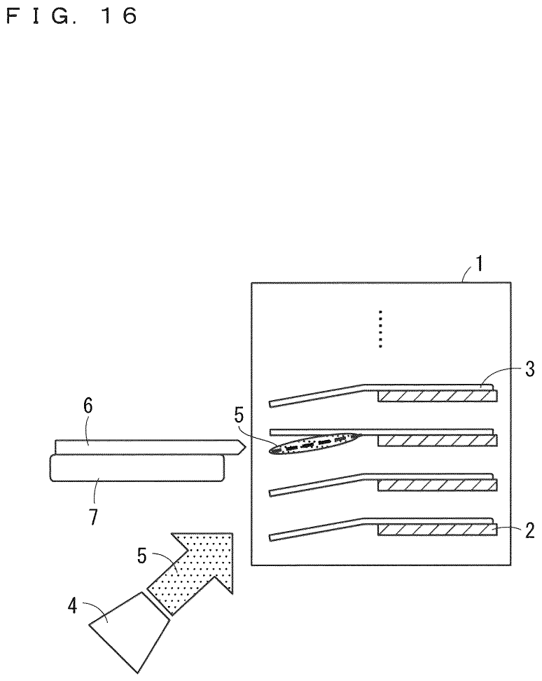

FIGS. 16 to 19 are diagrams for explaining a semiconductor manufacturing method according to the embodiment 2. Described hereinafter is a method of taking out the third wafer 3 (the target wafer 3) from the bottom from the cassette 1.

As illustrated in FIG. 16, the position and the angle of the air generator 4 are adjusted, and the air generator 4 blows the air 5 from below to only the target wafer 3.

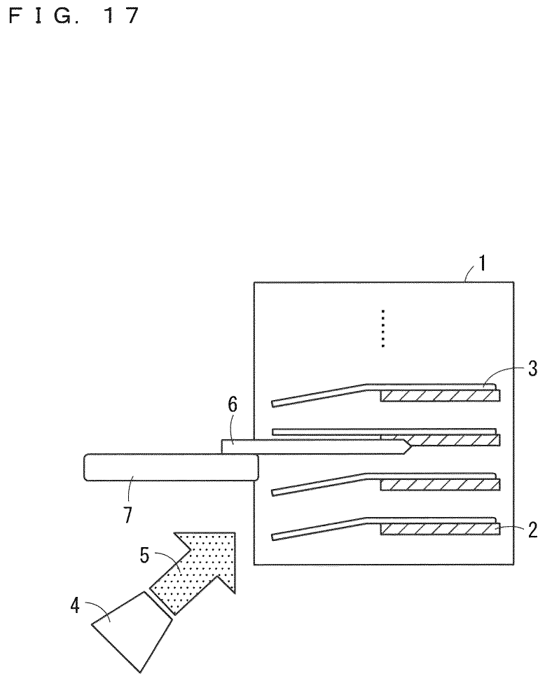

As illustrated in FIG. 17, the transfer robot 7 gets close to the cassette 1, and the robot hand 6 is inserted below the target wafer 3.

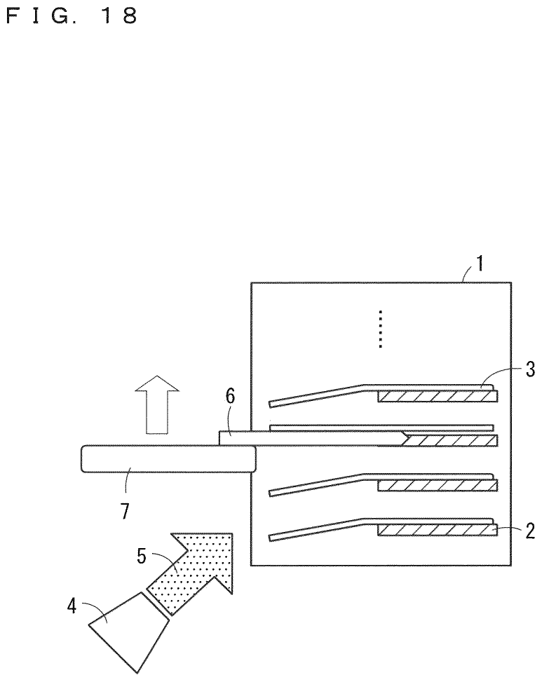

As illustrated in FIG. 18, the target wafer 3 is raised from the support portion 2 using the robot hand 6. Accordingly, the target wafer 3 is disposed on the robot hand 6.

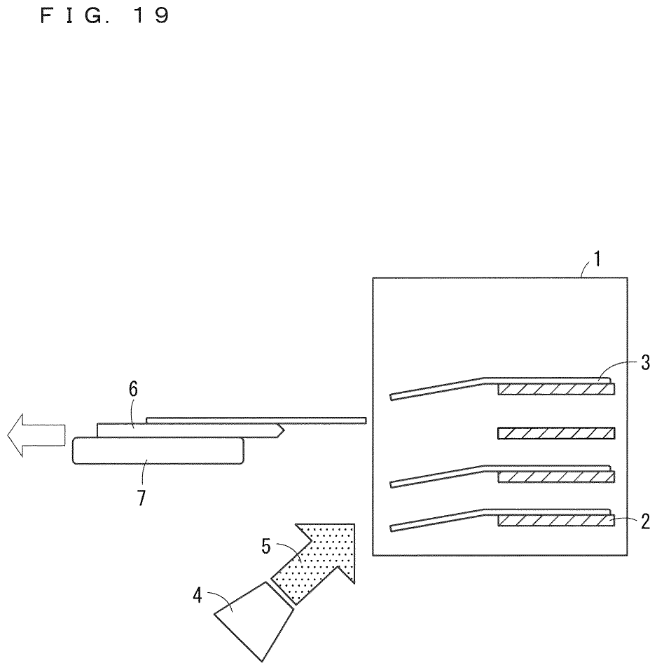

As illustrated in FIG. 19, the robot hand 6 is pulled out from the cassette 1. Accordingly, the target wafer 3 is taken out from the cassette 1. Subsequently, the transfer robot 7 transfers the target wafer 3 to various processing rooms.

According to the embodiment 2, the position and the angle of the air generator 4 are adjusted. Thus, the air 5 is prevented from being blocked by the other wafer 3, and the air 5 can be blown to the desired wafer 3 with pinpoint accuracy.

Although described above is the case of adjusting both the position and the angle of the air generator 4, any one of the position and the angle of the air generator 4 may also be adjusted.

### Embodiment 3

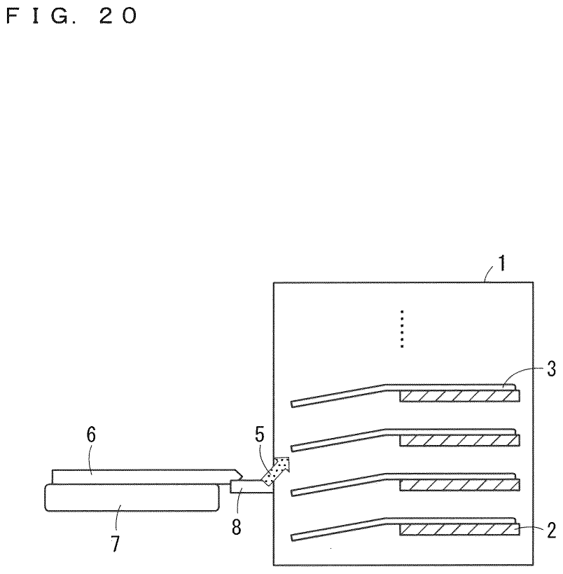

FIG. 20 is a diagram illustrating an example of a configuration of a semiconductor manufacturing device according to an embodiment 3. As illustrated in FIG. 20, in the semiconductor manufacturing device according to the embodiment 3, the robot hand 6 includes an air ejection hole 8 in a distal end. The other configuration is similar to that of the semiconductor manufacturing device according to the embodiment 1.

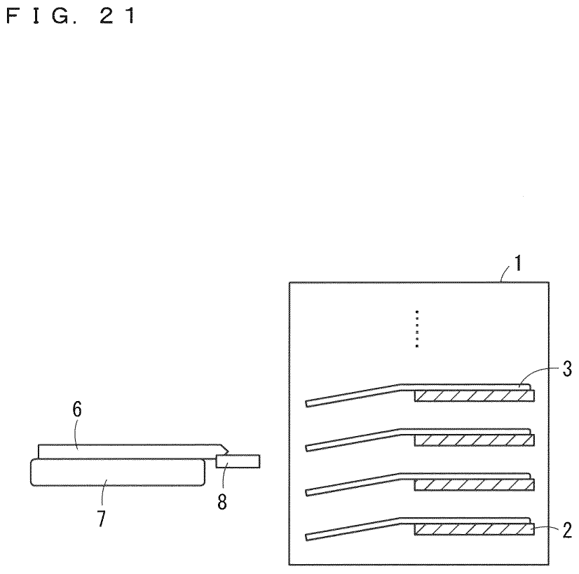

FIGS. 21 to 27 are diagrams for explaining a semiconductor manufacturing method according to the embodiment 3. Described hereinafter is a method of taking out the third wafer 3 (the target wafer 3) from the bottom from the cassette 1.

As illustrated in FIG. 21, the front side of each wafer 3 disposed on the support portion 2 in the cassette 1 sags, and the center portion thereof is warped. When the robot hand 6 is inserted below the target wafer 3 in such a state, the robot hand 6 has contact with the target wafer 3.

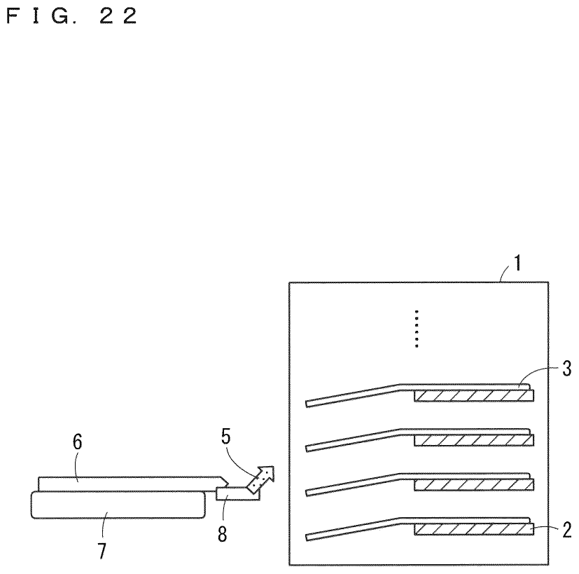

As illustrated in FIG. 22, the robot hand 6 blows the air 5 to the target wafer 3 from the air ejection hole 8.

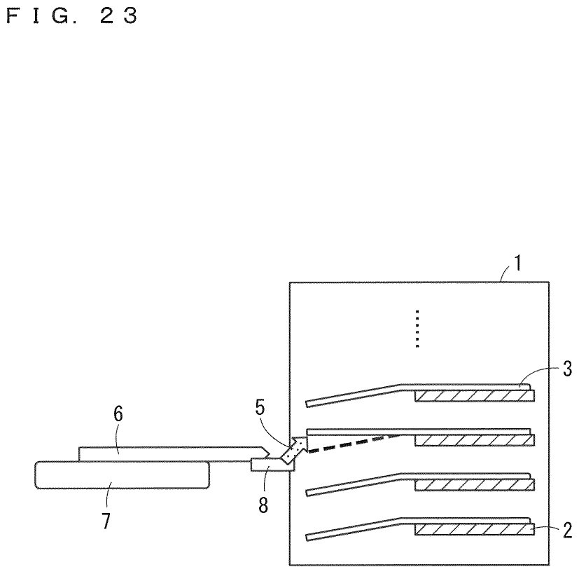

As illustrated in FIG. 23, when the air 5 is blown to the target wafer 3 from the air ejection hole 8, the sag (a broken line in FIG. 23) of the target wafer 3 is reduced. Although not shown in FIG. 23, the warpage of the target wafer 3 is also reduced.

As described in the embodiment 1, a flow rate and pressure of the air 5 ejected from the air ejection hole 8 may be adjusted in accordance with at least one of the sag and the warpage of the target wafer 3.

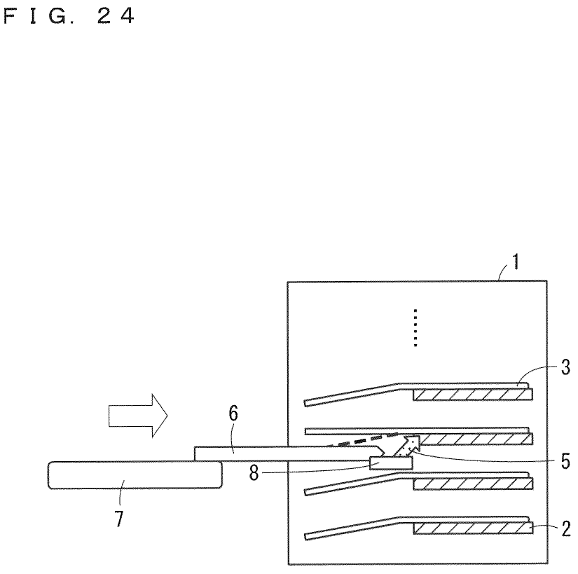

As illustrated in FIG. 24, the transfer robot 7 gets close to the cassette 1, and the robot hand 6 is inserted below the target wafer 3. At this time, the air 5 is being ejected from the air ejection hole 8.

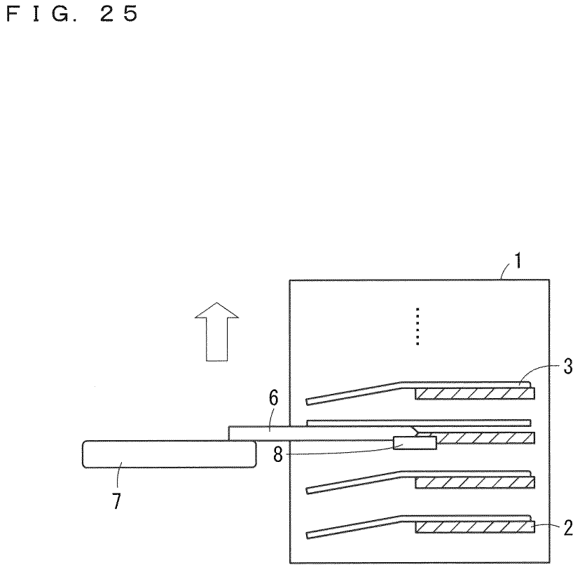

As illustrated in FIG. 25, the target wafer 3 is raised from the support portion 2 using the robot hand 6. Accordingly, the target wafer 3 is disposed on the robot hand 6. At this time, ejection of the air 5 from the air ejection hole 8 is stopped.

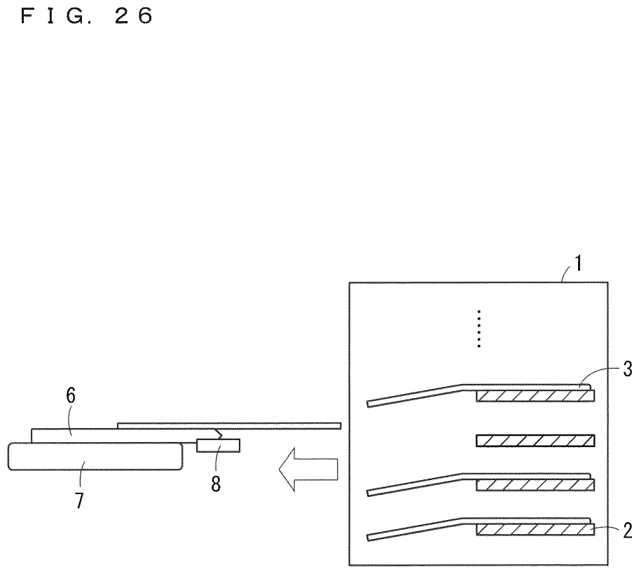

As illustrated in FIG. 26, the robot hand 6 is pulled out from the cassette 1. Accordingly, the target wafer 3 is taken out from the cassette 1. Subsequently, the transfer robot 7 transfers the target wafer 3 to various processing rooms.

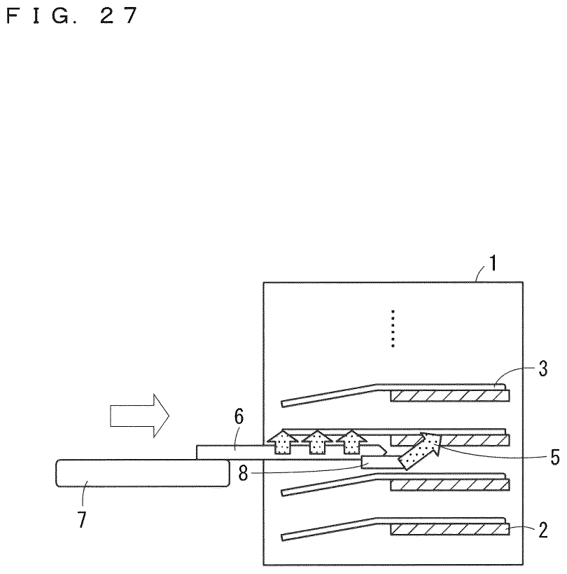

Although described above is the case of providing the air ejection hole 8 in the distal end of the robot hand 6, the configuration is not limited thereto. As illustrated in FIG. 27, the air ejection hole 8 may also be provided to a surface facing a lower side of the wafer 3 in the robot hand 6. The air ejection hole 8 may be provided to at least one of the distal end of the robot hand 6 and a surface of the robot hand 6 facing the lower side of the wafer 3.

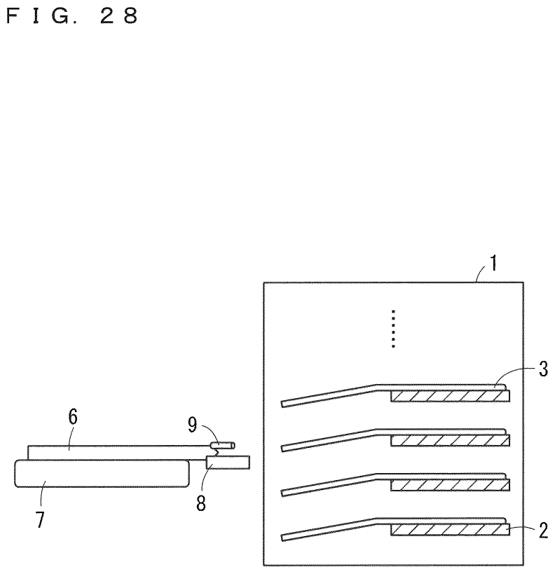

As illustrated in FIG. 28 to 30, the robot hand 6 may include a wafer detector 9 detecting the wafer 3. Described hereinafter is a method of taking out the third wafer 3 (the target wafer 3) from the bottom from the cassette 1.

As illustrated in FIG. 28, the front side of each wafer 3 disposed on the support portion 2 in the cassette 1 sags, and the center portion thereof is warped. When the robot hand 6 is inserted below the target wafer 3 in such a state, the robot hand 6 has contact with the target wafer 3.

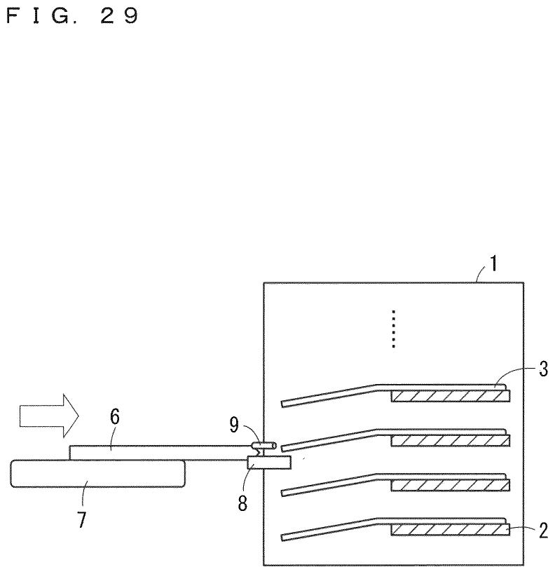

As illustrated in FIG. 29, when the transfer robot 7 gets close to the cassette 1 and the robot hand 6 is inserted below the target wafer 3, the wafer detector 9 detects the target wafer 3, and determines whether or not the robot hand 6 has contact with the target wafer 3. Then, when the wafer detector 9 determines that the robot hand 6 come into contact with the target wafer 3, the wafer detector 9 temporarily stops the robot hand 6.

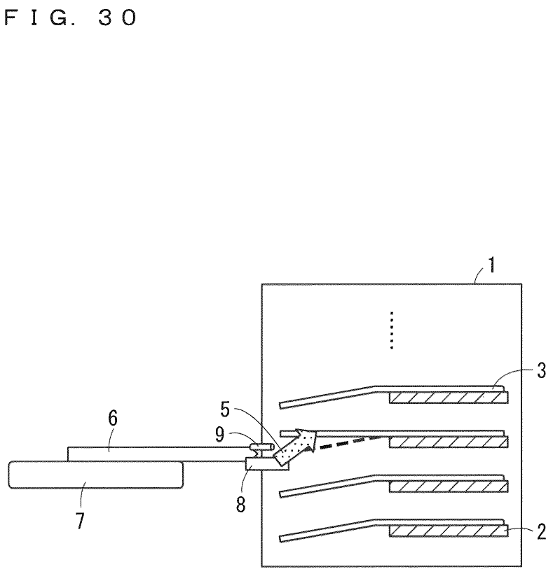

As illustrated in FIG. 30, the air 5 is blown to the target wafer 3 from the air ejection hole 8. Accordingly, the sag (a broken line in FIG. 30) of the target wafer 3 is reduced. Although not shown in FIG. 30, the warpage of the target wafer 3 is also reduced. Subsequently, the target wafer 3 is taken out from the cassette 1 using the robot hand 6.

According to the embodiment 3, the air ejection hole 8 is provided to at least one of the distal end of the robot hand 6 and the surface of the robot hand 6 facing the lower side of the wafer 3. Thus, the air 5 can be reliably blown to the target wafer 3, and the target wafer 3 can be taken out from the cassette 1 while suppressing the sag and the warpage of the target wafer 3. When the wafer detector 9 is provided to the robot hand 6, contact of the robot hand 6 with the target wafer 3 can be reliably prevented.

Each embodiment can be arbitrarily combined, or each embodiment can be appropriately varied or omitted within the scope of the present disclosure.

### Appendix

The aspects of the present disclosure are collectively described hereinafter as appendixes.

### (Appendix 1)

A semiconductor manufacturing method of manufacturing a semiconductor device includes steps of:
(a) blowing air to at least one wafer disposed on a support portion in a cassette from below using at least one air generator disposed on an outer portion of the cassette; and
(b) raising the wafer from the support portion to take out the wafer from the cassette using a robot hand while blowing the air to the wafer, wherein
in the step (a), the air generator blows the air toward half of a range of a side of taking out the wafer from the cassette in the wafer.

### (Appendix 2)

The semiconductor manufacturing method according to Appendix 1, wherein
in the step (a), the air generator ejects the air to a whole width direction of the cassette.

### (Appendix 3)

The semiconductor manufacturing method according to Appendix 1, wherein
the air generators are disposed in a plurality of positions away from a movement route of the robot hand.

### (Appendix 4)

The semiconductor manufacturing method according to any one of Appendixes 1 to 3, wherein
in the step (a), the air generator adjusts a flow rate and pressure of the air in accordance with a warpage of the wafer.

### (Appendix 5)

The semiconductor manufacturing method according to any one of Appendixes 1 to 4, wherein
in the step (a), the air generator moves in a direction in which the plurality of wafers are disposed and blows the air to a specific wafer in the plurality of wafers.

### (Appendix 6)

The semiconductor manufacturing method according to any one of Appendixes 1 to 5, wherein
in the step (a), the air generator changes an angle to a direction in which the plurality of wafers are disposed and blows the air to a specific wafer in the plurality of wafers.

### (Appendix 7)

A semiconductor manufacturing method of manufacturing a semiconductor device includes steps of:
(a) when inserting a robot hand below a specific wafer in at least one wafer disposed on a support portion in a cassette, blowing air to the specific wafer from an air ejection hole provided to at least one of a distal end of the robot hand and a surface of the robot hand facing a lower side of the wafer; and
(b) raising the specific wafer from the support portion to take out the specific wafer from the cassette using the robot hand while blowing the air to the wafer.

### (Appendix 8)

The semiconductor manufacturing method according to Appendix 7, wherein
in the step (a), the robot hand gets close to the specific wafer without blowing the a and blows the air when the specific wafer is detected.

### (Appendix 9)

A semiconductor manufacturing device manufacturing a semiconductor device includes:
a cassette including a support portion in which at least one wafer is disposed;
an air generator disposed on an outer portion of the cassette and blowing air to the wafer from below; and
a robot hand raising the wafer from the support portion to take out the wafer from the cassette while the air is blown to the wafer, wherein
the air generator blows the air toward half of a range of a side of taking out the wafer from the cassette in the wafer.

### (Appendix 10)

The semiconductor manufacturing device according to Appendix 9, wherein
the air generator ejects the air to a whole width direction of the cassette.

### (Appendix 11)

The semiconductor manufacturing device according to Appendix 9, wherein
the air generators are disposed in a plurality of positions away from a movement route of the robot hand.

### (Appendix 12)

The semiconductor manufacturing device according to any one of Appendixes 9 to 11, wherein
the air generator adjusts a flow rate and pressure of the air in accordance with a warpage of the wafer.

### (Appendix 13)

The semiconductor manufacturing device according to any one of Appendixes 9 to 12, wherein
the air generator includes a movement mechanism of moving in a direction in which the plurality of wafers are disposed.

### (Appendix 14)

The semiconductor manufacturing device according to any one of Appendixes 9 to 13, wherein
the air generator includes an angle changing mechanism of changing an angle to a direction in which the plurality of wafers are disposed.

### (Appendix 15)

A semiconductor manufacturing device manufacturing a semiconductor device includes:
a cassette including a support portion in which at least one wafer is disposed; and
a robot hand including an air ejection hole provided to at least one of a distal end and a surface facing a lower side of the wafer, wherein
the robot hand raises a specific wafer in the at least one wafer from the support portion to take out the specific wafer from the cassette while blowing air to the specific wafer from the air ejection hole.

### (Appendix 16)

The semiconductor manufacturing device according to Appendix 15, wherein
the robot hand includes a wafer detector detecting the specific wafer.

While the disclosure has been shown and described in detail, the foregoing description is in all aspects illustrative and not restrictive. It is therefore understood that numerous modifications and variations can be devised.

What is claimed is:

1. A semiconductor manufacturing method of manufacturing a semiconductor device, comprising steps of:
(a) blowing air to at least one wafer disposed on a support portion in a cassette from below using at least one air generator disposed on an outer portion of the cassette; and
(b) raising the wafer from the support portion to take out the wafer from the cassette using a robot hand while blowing the air to the wafer, wherein
in the step (a), the air generator blows the air toward half of a range of a side of taking out the wafer from the cassette in the wafer.

2. The semiconductor manufacturing method according to claim 1, wherein
in the step (a), the air generator ejects the air to a whole width direction of the cassette.

3. The semiconductor manufacturing method according to claim 1, wherein
the air generators are disposed in a plurality of positions away from a movement route of the robot hand.

4. The semiconductor manufacturing method according to claim 1, wherein
in the step (a), the air generator adjusts a flow rate and pressure of the air in accordance with a warpage of the wafer.

5. The semiconductor manufacturing method according to claim 1, wherein
in the step (a), the air generator moves in a direction in which the plurality of wafers are disposed and blows the air to a specific wafer in the plurality of wafers.

6. The semiconductor manufacturing method according to claim 1, wherein
in the step (a), the air generator changes an angle to a direction in which the plurality of wafers are disposed and blows the air to a specific wafer in the plurality of wafers.

7. A semiconductor manufacturing method of manufacturing a semiconductor device, comprising steps of:
(a) when inserting a robot hand below a specific wafer in at least one wafer disposed on a support portion in a cassette, blowing air to the specific wafer from an air ejection hole provided to at least one of a distal end of the robot hand and a surface of the robot hand facing a lower side of the wafer; and
(b) raising the specific wafer from the support portion to take out the specific wafer from the cassette using the robot hand while blowing the air to the wafer.

8. The semiconductor manufacturing method according to claim 7, wherein
in the step (a), the robot hand gets close to the specific wafer without blowing the air and blows the air when the specific wafer is detected.

9. A semiconductor manufacturing device manufacturing a semiconductor device, comprising:
a cassette including a support portion in which at least one wafer is disposed;
an air generator disposed on an outer portion of the cassette and blowing air to the wafer from below; and
a robot hand raising the wafer from the support portion to take out the wafer from the cassette while the air is blown to the wafer, wherein
the air generator blows the air toward half of a range of a side of taking out the wafer from the cassette in the wafer.

10. The semiconductor manufacturing device according to claim 9, wherein
the air generator ejects the air to a whole width direction of the cassette.

11. The semiconductor manufacturing device according to claim 9, wherein
the air generators are disposed in a plurality of positions away from a movement route of the robot hand.

12. The semiconductor manufacturing device according to claim 9, wherein
the air generator adjusts a flow rate and pressure of the air in accordance with a warpage of the wafer.

13. The semiconductor manufacturing device according to claim 9, wherein
the air generator includes a movement mechanism of moving in a direction in which the plurality of wafers are disposed.

14. The semiconductor manufacturing device according to claim 9, wherein
the air generator includes an angle changing mechanism of changing an angle to a direction in which the plurality of wafers are disposed.

15. A semiconductor manufacturing device manufacturing a semiconductor device, comprising:
a cassette including a support portion in which at least one wafer is disposed; and
a robot hand including an air ejection hole provided to at least one of a distal end and a surface facing a lower side of the wafer, wherein
the robot hand raises a specific wafer in the at least one wafer from the support portion to take out the specific wafer from the cassette while blowing air to the specific wafer from the air ejection hole.

16. The semiconductor manufacturing device according to claim 15, wherein
the robot hand includes a wafer detector detecting the specific wafer.
